(19) United States
(12) Patent Application Publication
(10) Pub. No.: US 2007/0122991 A1
(43) Pub. Date: May 31, 2007

(54) RESISTOR ELEMENT AND MANUFACTURING METHOD THEREOF

(75) Inventor: Takayuki Nagai, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation

(21) Appl. No.: 11/561,643

(22) Filed: Nov. 20, 2006

(30) Foreign Application Priority Data
Nov. 25, 2005 (JP) 2005-339745

(51) Int. Cl. H01L 23/62; H01L 21/20

(52) U.S. Cl. 438/382; 257/358

(57) ABSTRACT

A method of manufacturing a resistive element of present invention comprises; (A) forming on a substrate, a polysilicon structure whose top layer is a polysilicon layer; (B) forming a metal layer on the polysilicon layer; (C) forming an upper barrier layer on the metal layer; and (D) forming a silicide layer whose surface is covered with the upper barrier layer after the process (C) through a reaction between the polysilicon layer and the metal layer. According to the present invention, a variation in a resistor element of a semiconductor device can be suppressed.

### BACKGROUND OF THE INVENTION

1. Field of the Invention

The present invention relates to a resistor element in a semiconductor device and a manufacturing method thereof. Particularly, the present invention relates to a resistor element having silicide, and a manufacturing method thereof.

2. Description of the Related Art

The influence of a resistance of a gate electrode or source and drain electrodes upon a processing speed of device becomes remarkable with minimizing of a MOS transistor. In order to reduce the resistivity of these electrodes, a technology using silicide is conventionally known (for example, see Japanese Laid Open Patent Application (JP-P 2001-223177A) and Japanese Laid Open Patent Application (JP-A-Heisei 7-201775)). The gate electrode to which the silicide technology is applied has a polycide structure which includes a polysilicon layer and a silicide layer. The silicide layer is formed by the silicidation process between a polysilicon film and the metal film deposited thereon. Here, since the silicidation progresses rapidly, generally it is difficult to form a silicide layer of uniform thickness.

The technology for making the interface of a polysilicon layer and a silicide layer uniform is described in Japanese Laid Open Patent Application (JP-P 2001-223177A) about the polycide gate electrode of a MOS transistor. The polycide gate electrode indicated in this document includes the polysilicon layer, a diffusion barrier layer, and the silicide layer. The polysilicon layer is formed in the predetermined part of a semiconductor substrate. The diffusion barrier layer is formed on an upper surface of the polysilicon layer and is electrically conductive, and prevents diffusion of metal atoms. The silicide layer includes metal atoms, and is formed on an upper surface of the diffusion barrier layer. Since the diffusion barrier layer prevents the diffusion of metal atoms, it is expected that the interface of the polysilicon layer and the silicide layer will be formed uniformly.

As a related technology, in Japanese Laid Open Patent Application (JP-P 2002-110966A) and Japanese Laid Open Patent Application (JP-P 2002-110967A), a gate electrode of the MOS transistor which has a lamination structure of a first conductive layer and a second conductive layer is described.

According to Japanese Laid Open Patent Application (JP-P 2002-110966A), a MOS transistor is manufactured by the following continuous processes including the steps of: (1) forming a gate insulating layer and a silicone layer on a semiconductor layer; (2) forming a sidewall insulating layer in the side of the silicone layer; (3) forming sauce/drain in the semiconductor layer; (4) forming a planarized interlayer insulating layer; (5) removing the silicone layer for preventing the gate insulating layer from being exposed, and forming a concave portion; (6) partially filling the concave portion with a metal layer, (7) capping a protective insulating layer on the concave portion after the metal layer is filled; and (8) etching the interlayer insulating layer to form a through hole. Since the gate electrode is protected by the sidewall insulating layer and the protective insulating layer, the gate electrode is prevented from being exposed upon forming through hole in the process (8).

According to Japanese Laid Open Patent Application (JP-P 2002-110967A), a MOS transistor is manufactured by the following continuous process including steps of: (1) forming a first polysilicon layer on a gate insulating layer; (2) forming a silicon nitride layer on the first polysilicon layer; (3) forming a second polysilicon layer on the silicon nitride layer; (4) forming a sidewall spacer; (5) forming an interlayer insulating layer covering the second polysilicon layer; (6) planarizing the interlayer insulating layer until the upper surface of the second polysilicon layer is exposed; (7) removing the second polysilicon layer; (8) removing the silicon nitride layer and forming a concave portion; and (9) filling the concave portion with a metal layer and forming the gate electrode including at least the first polysilicon layer and the metal layer.

An analog gradation voltage corresponding to image data of digital format is applied to pixels of a liquid crystal display. Therefore, a gradation voltage determination circuit for determining a gradation voltage corresponding to the image data is installed in a liquid crystal display driver.

FIG. 1 shows a construction for a general gradation voltage determination circuit installed in the liquid crystal display driver. The gradation voltage determination circuit can output, for example, corresponding to 6-bit digital image signals D0-D5, output voltages (gradation voltages) V0-V63 of 64 gradation sequences. More specifically, the gradation voltage determination circuit includes a gradation voltage generating circuit 200 and a D/A conversion circuit 210. The gradation voltage generating circuit 200 includes a resistor array including the resistors R1-R63 connected in series. The reference voltage Vref0-Vref9 inputted from a power supply circuit is suitably divided in the resistor array; thereby the gradation voltages V0-V63 of 64 steps are generated. The D/A conversion circuit 210 chooses one gradation voltage from these gradation voltages V0-V63 corresponding to a digital image signals D0-D5. One selected gradation voltage is outputted from an output terminal OUT, and is applied to a pixel.

The demand of liquid crystal displays is expanded increasingly, and a liquid crystal display in which a high-definition display is possible is desired in recent years. In order to realize a high-definition display, it is indispensable that the gradation voltage generating circuit 200 generates gradation voltages V0-V63 with sufficient accuracy. When gradation voltages V0-V63 vary from desired preset values, it becomes difficult to obtain the desired natural gradation display, In order to suppress the variation in the gradation voltages V0-V63, it is desired to prevent the manufacturing fluctuation in the resistors R1-R63 is desired. That is, in the field of the liquid crystal display, a technology in which a high-precision resistor can be manufactured is desired.

As a resistor element of the gradation voltage generating circuit 200, it is possible to use a polysilicon resistor (gate resistor) In order to suppress the resistance of the polysilicon resistor, it is possible to apply the above-mentioned silicide technology. However, since the silicidation progresses rapidly, it is difficult to control the thickness and the area of the silicide layer. The variation in the silicide layers causes variation in the resistances of the polysilicon resistors, thereby causing a fault in gradation display as a result.

### SUMMARY OF THE INVENTION

In a first aspect of present invention, a manufacturing method of a resistor element is provided. The manufacturing method includes; (A) forming a polysilicon structure 50 whose top layer is a polysilicon layer 30, 32 on a substrate 10; (B) forming a metal layer 70 on the polysilicon layer 30, 32; (C) forming an upper barrier layer 42 on the metal layer 70; and (D) forming a silicide layer 80 whose upper surface S80 is covered with the upper barrier layer 42 after the process (C) through a reaction between the polysilicon layer 30,32 and the metal layer 70. Therefore, it becomes possible to control a grain growth in an upward direction during the silicidation and suppress a variation in a thickness of the silicide layer 80, i.e., a variation of the resistive element.

The present invention preferably includes following processes between the process (A) and (B); (E) forming a sidewall 60 on a side of the polysilicon structure 50; and (F) removing a portion of the polysilicon layer 30,32 after the process (E) to form a space surrounded by an upper surface 830,32 of the polysilicon structure 50 and the sidewall 60. In this case, the metal layer 70 is formed in the space during the step (B). The silicide layer 80 is formed so that a side thereof is surrounded by the sidewall 60 during the process (D). Therefore, it becomes possible to control a grain growth in a side direction during the silicidation and suppress a variation in an area size of the silicide layer 80, i.e, a variation in a resistor element.

Further preferably, the process (A) includes: (a1) forming a lower polysilicon layer 31 on the substrate 10, (a2) forming a lower barrier layer 41 on the lower polysilicon layer 31, and (a3) forming an upper polysilicon layer 32 on the lower barrier layer 41 as the polysilicon layer. In this case, during the process (D), the silicide layer 80 is formed so that an upper surface thereof and bottom thereof are covered with the barrier layer 42, 41 respectively. Therefore, it becomes possible to control a grain growth in upward and downward direction during the silicidation and suppress the variation in a thickness of silicide layer 80, i.e, the variation in the resistor element.

In a second aspect of present invention, resistor element 1 is provided. The resistor element 1 of present invention includes: a polysilicon layer 31 formed on a substrate 10; a lower barrier layer 41 formed on the polysilicon layer 31; a silicide layer 80 formed on the lower barrier layer 41; and an upper barrier layer 42 formed on the silicide layer 80.

According to the resistor element and the manufacturing method of the present invention, a grain growth in the silicidation is controlled. As a result, the variation of the area size and the thickness of a silicide layer which is formed are controlled. Therefore, the resistance variation in the silicide layer is controlled and the variation in the resistance of the whole resistor elements is also controlled. This leads to an improvement in there liability of the product employing the resistor element as a part of circuit.

### BRIEF DESCRIPTION OF THE DRAWINGS

FIG. 1 is a schematic diagram illustrating the construction of the gradation voltage determination circuit in a liquid crystal display;

FIG. 2 is a plane view illustrating the structure of a resistor element according to the first embodiment of the present invention;

FIG. 3 is a sectional view illustrating the structure of the resistor element according to the first embodiment;

FIGS. 4A to 4K are sectional views illustrating the manufacturing process of the resistor element according the first embodiment;

FIGS. 5A to 5D are sectional views illustrating the manufacturing process of the resistor element according to the second embodiment; and

FIGS. 6A to 6E are sectional views illustrating the manufacturing process of the resistor element according to the second embodiment.

### DESCRIPTION OF THE PREFERRED EMBODIMENTS

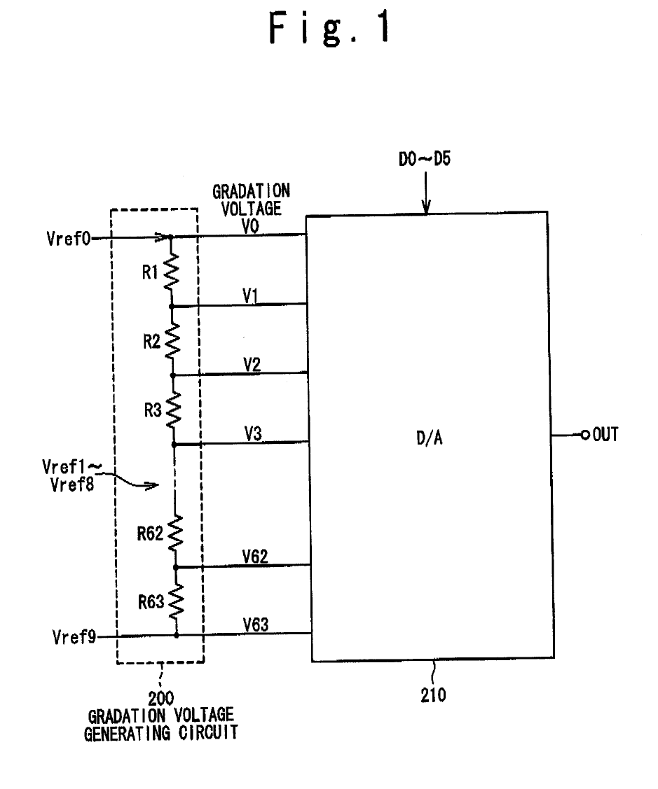

Referring to accompanying drawings, the resistor element in the semiconductor device according to embodiments of the present invention and a manufacturing method thereof are described. The resistor element (polysilicon resistor) of the present embodiment has a silicide structure which is formed with a silicide technology. The resistor element of the present embodiment is applied to the gradation voltage generating circuit 200 in a liquid crystal display as shown in FIG. 1, for example. As described above, a high-precision resistor element is required for a high-definition liquid crystal display, and it is particularly preferable that the present invention is applied to the gradation voltage generating circuit in the liquid crystal display.

### 1. First Embodiment

1-1. Structure

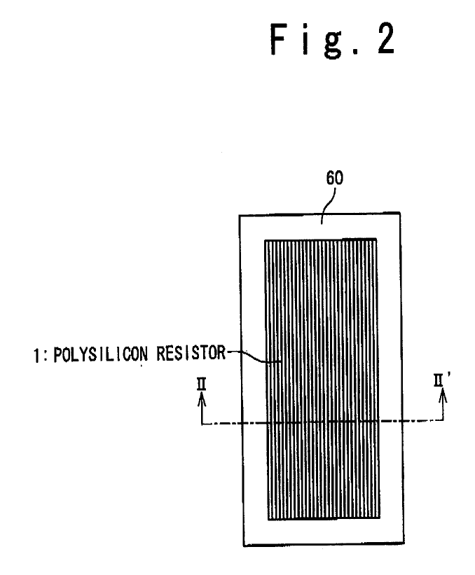

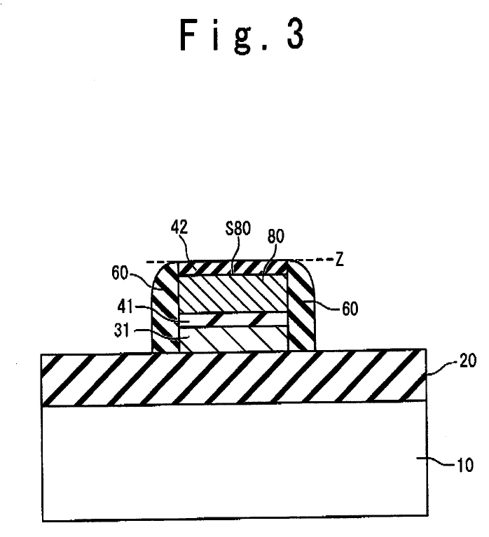

FIG. 2 is a plan view illustrating the structure of the resistor element of the first embodiment. The resistor element according to the present embodiment is provided with a polysilicon resistor 1 which has a predetermined area within a plane. The polysilicon resistor 1 is surrounded by a sidewall 60 in the plane. The sectional view along the line II-II′ in the figure is shown in FIG. 3.

As shown in FIG. 3, an element separation structure 20 is formed into a substrate 10. The substrate 10 is a P-type silicon substrate, for example. The element separation structure 20 is STI (Shallow Trench Isolation) structure or LOCOS (LOCal Oxidation of Silicon) structure. Furthermore, the structure corresponding to the polysilicon resistor 1 is formed in a predetermined position on the substrate 10. Specifically, a polysilicon layer 31 is formed on the substrate 10 (element separation structure 20), a lower barrier layer 41 is formed on the polysilicon layer 31, a silicide layer 80 is formed on the lower barrier layer 41, and an upper barrier layer 42 is formed on the silicide layer 80.

The lower barrier layer 41 and the upper barrier layer 42 are the layers (diffusion barrier layer) which prevent diffusion of metal atoms while maintaining an electrical continuity. For example, these barrier layers 41 and 42 are thin oxide films which have about 10 A film thickness. The barrier layers 41 and 42 may be formed with a nitride film, or an oxynitride film, etc. besides an oxide film. As shown in FIG. 3, the silicide layer 80 is sandwiched between the lower barrier layer 41 and the upper barrier layer 42. For example, the silicide layer 80 is a TiSi film and is formed by the silicidation between Ti and polysilicon. As described below, in the silicidation, the barrier layers 41 and 42 prevent the diffusion of the metal atoms.

Furthermore, sides of the polysilicon layer 31, the upper and lower barrier layers 41 and 42, and the silicide layer 80 are surrounded by the sidewall 60 which is an insulated film, In particular, it is noted that all the sides of silicide layer 80 are surrounded by the sidewall 60. In other words, an upper surface S80 of the silicide layer 80 is located at least lower than an uppermost part (shown by symbol Z in the figure) of the sidewall 60.

An upper surface of the upper barrier layer 42 is formed so that it may be substantially aligned with the uppermost part of the sidewall 60.

Thus, all surfaces of the silicide layer 80 are completely covered with the lower barrier layer 41, the upper barrier layer 42, and the sidewall 60.

Conversely, it can be said that these barrier layers 41 and 42 and the sidewall 60 define the size of the silicide layer 80. From this point of view, these barrier layers 41 and 42 and the sidewall 60 can be called a barrier structure for specifying the size of the silicide layer 80. It can be said that the resistor element (polysilicon resistor 1) according to the present embodiment includes the barrier structure with the polysilicon layer 31, the silicide layer 80 and the barrier structure. As shown below, it is possible to control the size of the silicide layer 80 by this barrier structure completely.

1-2. Manufacturing Method

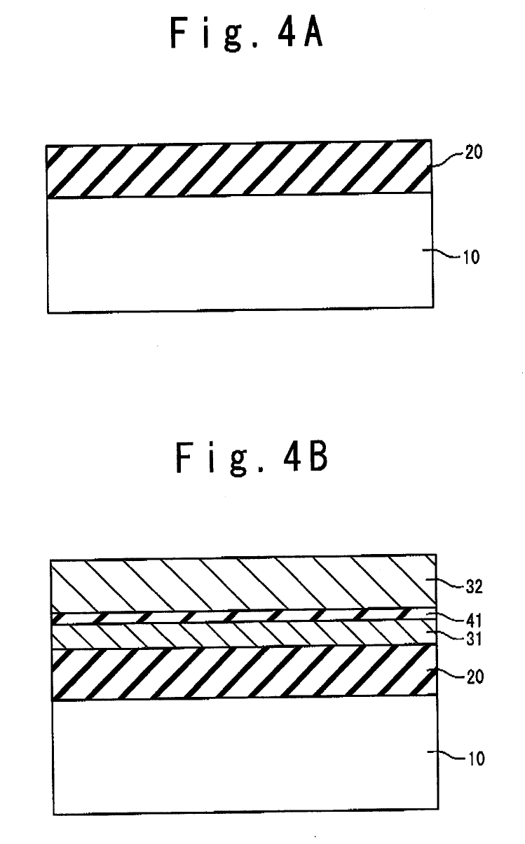

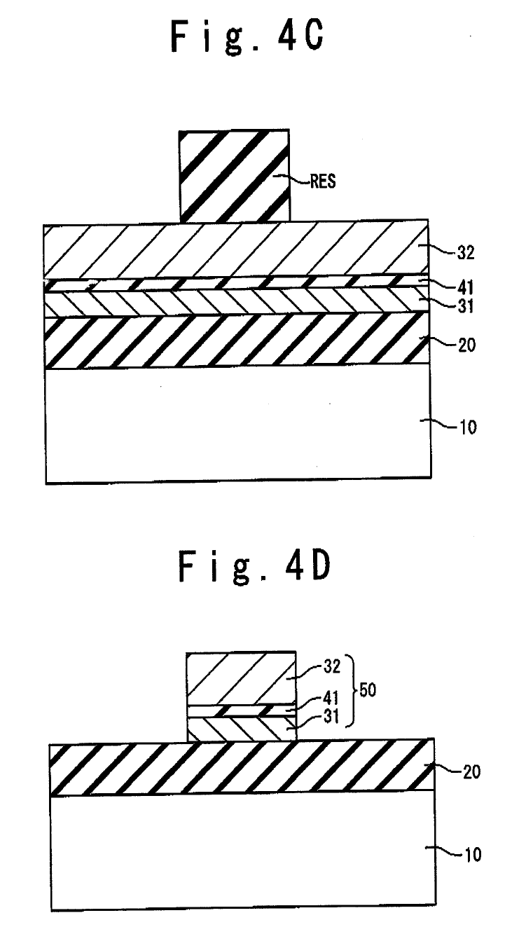

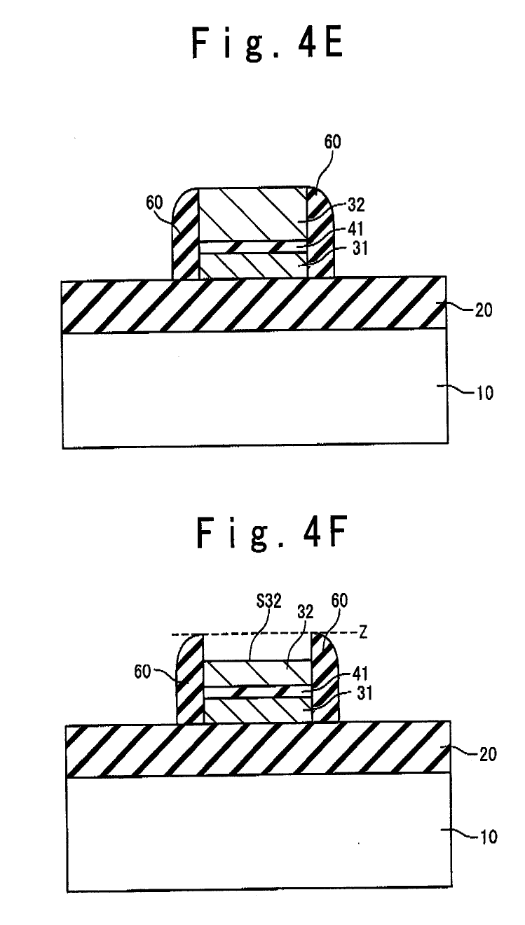

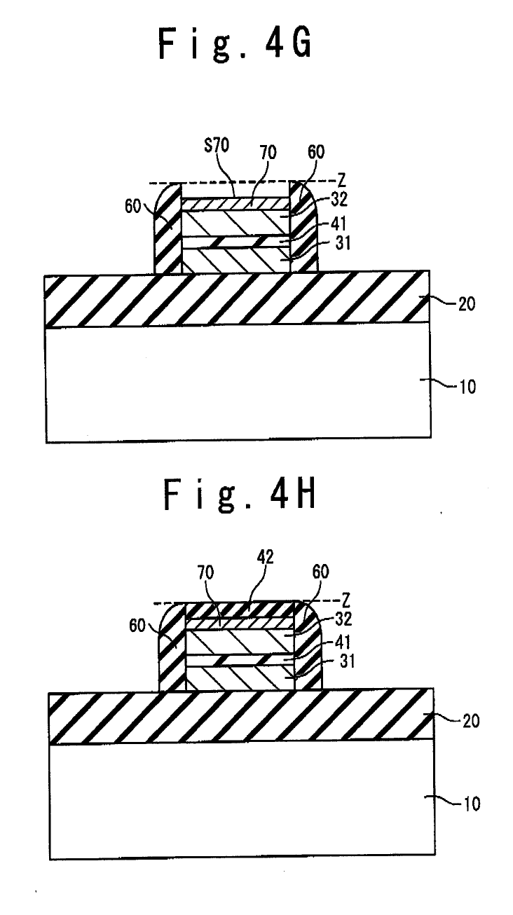

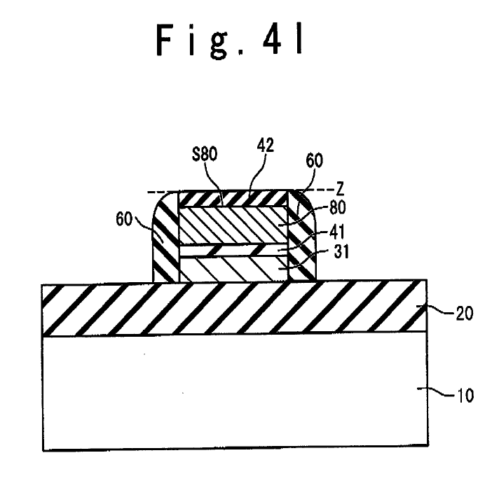

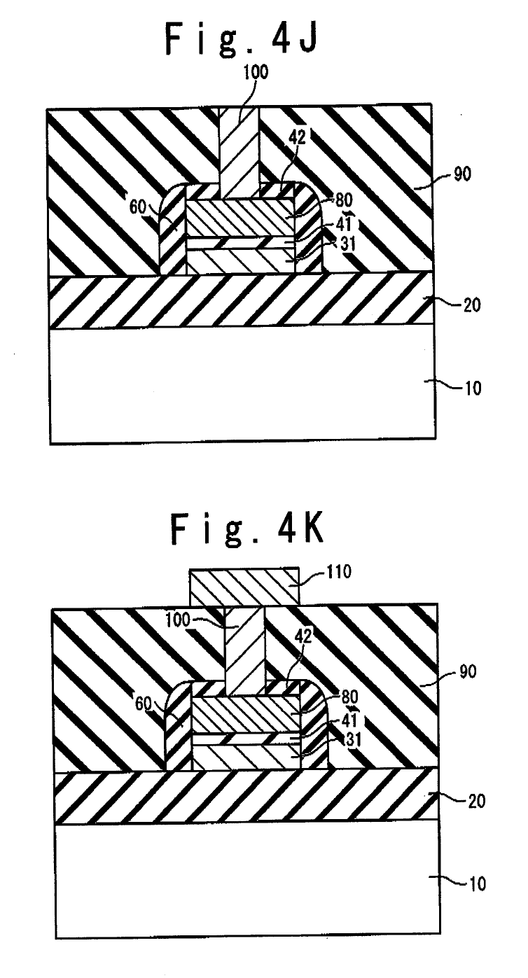

FIGS. 4A-4K show the manufacturing process of the resistor element concerning the present embodiment in order, and show the sectional structure as FIG. 3.

First, as shown in FIG. 4A, the element separation structure 20 is formed in the substrate 10. The substrate 10 is a P-type silicon substrate which has the resistivity of 15 Ω·cm, for example. The element separation structure 20 is formed by the STI method or the LOCos method, and the depth thereof is about 1000 A to about 5 μm.

Subsequently, as shown in FIG. 4B, the lower polysilicon layer 31 with a thickness of 500 A is formed on the substrate 10 (element separation structure 20). Then, the lower barrier layer 41 is formed on the lower polysilicon layer 31. This lower barrier layer 41 is a thin oxide film with a film thickness of about 10 A, and it prevents the diffusion of the metal atoms, for example, while maintaining the electrical continuity. In addition, the lower barrier layer 41 may be formed with the nitride film, the oxynitride film, etc. besides the oxide film. Then, an upper polysilicon layer 32 with a thickness of 1000 A is formed on the lower barrier layer 41.

Subsequently, as shown in FIG. 4C, a resist mask RES is formed in the predetermined position on the upper polysilicon layer 32. The predetermined position is a desired position where a polysilicon resistor is formed.

Subsequently, etching of the upper polysilicon layer 32, the lower barrier layer 41, and the lower polysilicon layer 31 is performed by using the resist mask RES. As a result, as shown in FIG. 4D, a “polysilicon structure 50” which is a lamination film of the lower polysilicon layer 31 after etching, the lower barrier layer 41, and the upper polysilicon layer 32 is acquired. The polysilicon structure 50 has the pattern according to the resist mask RES, i.e., the pattern corresponding to the shape of the desired polysilicon resistor.

Subsequently, the sidewall 60 is formed in the both sides of the polysilicon structure 50 as shown in FIG. 4E. Specifically, the sidewall 60 is formed so as to surround the all sides of the polysilicon structure 50 (see FIG. 2) 2). This sidewall 60 is formed by performing an etch back, for example, after depositing the oxide film with a thickness of 1500 A.

Subsequently, the upper polysilicon layer 32 is selectively etched to about 500 A. This is realizable by a selectivity etching or an etching employing a photoresist. As a result, as shown in FIG. 4F, an upper surface S32 of the upper polysilicon layer 32 will be located lower than a topmost part (shown by symbol Z in the figure) of the sidewall 60. Thus, the “space” surrounded by the upper surface 532 of the upper polysilicon layer 32 and an internal surface of the sidewall 60 are formed by selectively removing a part of the top polysilicon layer 32.

Subsequently, as shown in FIG. 4G, a metal layer 70 for the silicidation is formed on the surface of the remaining upper polysilicon layer 32, i.e., the inside of the above “space.” The metal used for the silicidation includes titanium (Ti), cobalt (Co), nickel (Ni), tungsten (W), molybdenum (Ma), tantalum (Ta), platinum (Pt), palladium (Pd), and chromium (Cr).

For example, a Ti film with a thickness of 200 A is deposited on the upper polysilicon layer 32 as the metal layer 70. This metal layer 70 is also formed so that an upper surface S70 will be lower than a topmost part Z of the sidewall 60.

Subsequently, as shown in FIG. 4H, the upper barrier layer 42 is formed on the metal layer 70. The upper barrier layer 42 is formed with the oxide film, the nitride film, or the oxynitride film, and prevents the diffusion of the metal atoms. For example, the upper barrier layer 42 is a thin oxide film with a thickness of about 10 A. Preferably, the upper barrier layer 42 is formed so that the upper surface thereof may be substantially aligned with the topmost part Z of the sidewall 60.

Subsequently, a heat treatment is performed and the silicidation occurs between the upper polysilicon layer 32 and the metal layer 70. In this silicidation, grain cannot grow over the sidewall 60. That is, the sidewall 60 defines the limit of the range for a grain growth and controls the grain growth in a plane direction. Similarly, the lower barrier layer 41 and the upper barrier layer 42 control grain growth in a downward direction and an upward direction, respectively. As a result of such the silicidation, as shown in FIG. 4I, the silicide layer 80 (for example, TiSi) surrounded by the lower barrier layer 41, the top barrier layer 42 and the sidewall 60 is formed.

As shown in FIG. 41, the upper surface S80 of the silicide layer 80 is covered with the upper barrier layer 42. That is, the upper surface S80 of the silicide layer 80 is lower than the topmost part Z of the sidewall 60. The formed silicide layer 80 reaches to the lower barrier layer 41. The size of the formed silicide layer 80 is defined by the space surrounded by the barrier layers 41 and 42 and the sidewall 60. This means that the variation of the formed silicide layers 80 is prevented. Therefore, the variation in the resistance value of the resistor element including this silicide layer 80 is prevented.

Subsequently, as shown in FIG. 4J, an interlayer insulation film 90 is formed in the whole surface. Then, a contact hole which penetrates the interlayer insulation film 90 and the upper barrier layer 42 and reaches to the silicide layer 80 is formed. By filling the contact hole with tungsten, for example, a contact 100 for the silicide layer 80 of the polysilicon resistor 1 is formed.

Subsequently, as shown in FIG. 4K, a wiring layer 110, which has a predetermined pattern on the interlayer insulation film 90, is formed. This wiring layer 110 is formed so that it may connect with the suicide layer 80 via the contact 100. For example, the wiring layer 110 is formed of an Al film.

The silicide layer 80 and the lower polysilicon layer 31 25 function as a p, lysilicon resistor.

1-3. Effect

Since the silicidation progresses rapidly, generally the control of the same is difficult. According to the present embodiment, a whole metal and polysilicon for the silicidation are covered with the barrier structure formed with the oxide film etc. Therefore, the progress of the silicidation can be controlled so that the grain may not grow over the range surrounded with the barrier structure.

Specifically, the above-mentioned sidewall 60 plays a role to control growth of the grain in the plane direction in the silicidation. Therefore, after the sidewall 60 is formed in the side of the polysilicon structure 50 (see FIG. 4E), a part of the polysilicon structure 50 is selectively removed by etching (see FIG. 4F). Since the metal layer 70 is formed in the empty area, the upper surface S70 of the metal layer 70 will be lower than the topmost part of the sidewall 60 (see FIG. 4G). Since the sidewall 60 (insulated film) exists along the side circumference of the metal layer 70, the sidewall 60 functions as a barrier for the grain growth in the plane direction.

Furthermore, the lower barrier layer 41 functions as a barrier for the grain growth in the downward direction. In addition, the upper barrier layer 42 functions as the barrier for the grain growth in the upward direction. Therefore, the grain growth in the silicidation will be completely controlled over all the directions.

As explained above, according to the present embodiment, the grain growth in the silicidation is controlled in the plane direction and a perpendicular direction. As a result, the variation of the area and the thickness of the formed silicide layer 80 are prevented. Therefore, the variation in the resistances of the whole resistor elements is prevented, thus, the high-precision resistor elements are offered. This leads to an improvement in the reliability of the product employing the resistor element as a part of circuit. Particularly, from a viewpoint of displaying high-definition liquid crystal, the high precision resistor element according to the present embodiment is preferably applied to the gradation voltage generating circuit oft he liquid crystal display.

### 2. Second Embodiment

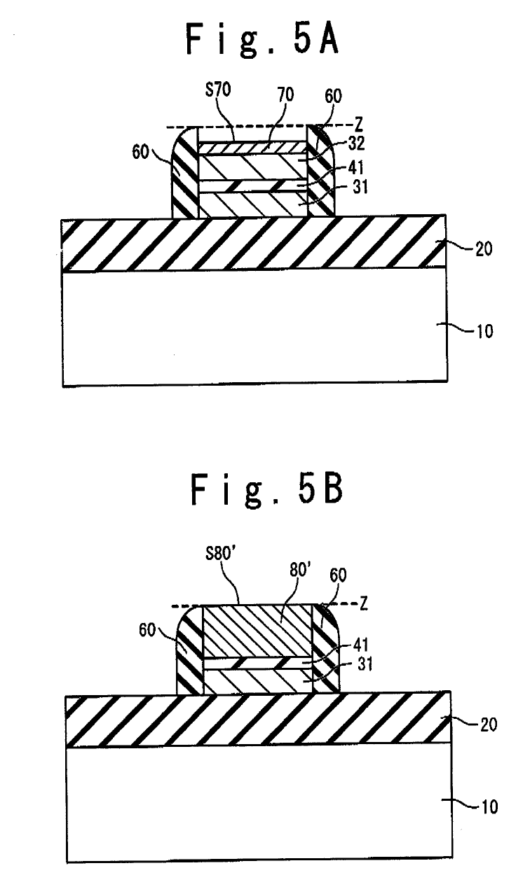

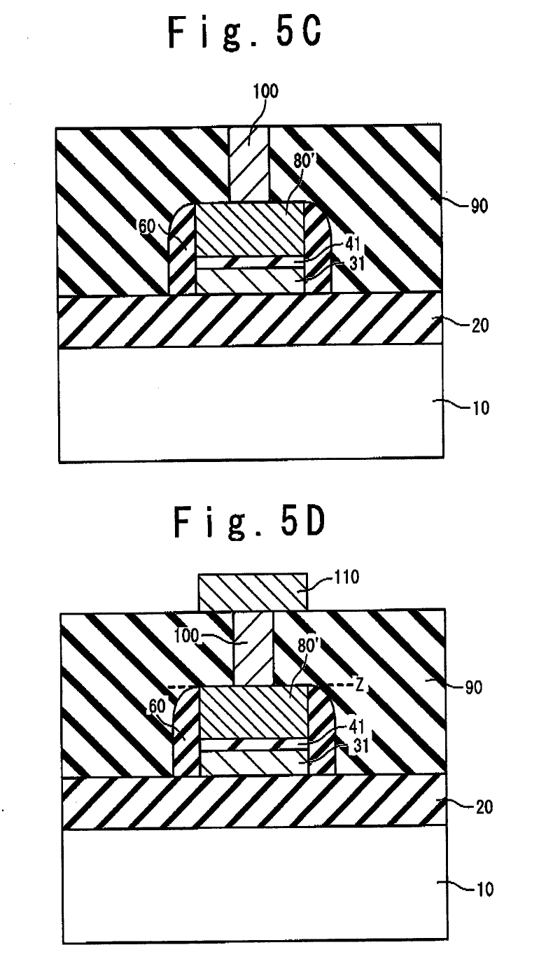

In a second embodiment of the present invention, the structure where the upper barrier layer 42 is eliminated from the resistor element according to the above mentioned first embodiment is described. Referring to FIGS. 5A-5D, the manufacturing process of the resistor element according to the present embodiment is described. The explanations which already have described in the first embodiment are suitably omitted for avoiding redundant description.

After the process shown in FIGS. 4A-4F is completed, the metal layer 70 for the silicidation is formed on the surface of the upper polysilicon layer 32. As a result, a structure shown in FIG. 5A is obtained. The metal layer 70 is a Ti film with the thickness of 200 A, for example. This metal layer 70 is formed so that the upper surface S70 will be lower than the topmost part Z of the sidewall 60.

Subsequently, a heat treatment is performed and the silicidation occurs between the upper polysilicon layer 32 and the metal layer 70. The grain cannot grow over the sidewall 60 in this silicidation. That is, the sidewall 60 defines the limit of the range that the grain is allowed to grow, and controls the grain growth in the plane direction. Similarly, the lower barrier layer 41 controls the grain growth in the downward direction. As a result of such the silicidation, as shown in FIG. 5B, a silicide layer 80′ (for example, TiSi) surrounded by the lower barrier layer 41 and the sidewall 60 is formed. An upper surface S80′ of the silicide layer 80′ is located lower than the topmost part Z of the sidewall 60.

Subsequently, as shown in FIG. 5C, the interlayer insulation film 90 is formed in the whole surface. Then, a contact hole which penetrates the interlayer insulation film 90 and reaches the silicide layer 80′ is formed. By filling the contact hole with tungsten, for example, the contact 100 for the silicide layer 80′ of the polysilicon resistor 1 is formed.

Subsequently, as shown in FIG. 5D, the wiring layer 110, which has a predetermined pattern on the interlayer insulation film 90, is formed. This wiring layer 110 is formed so that it may connect with the silicide layer 80′ via the contact 100. For example, the wiring layer 110 is formed of Al film.

The silicide layer 80′ and the lower polysilicon layer 31 function as a polysilicon resistor.

According to the present embodiment, the grain growth in the silicidation is controlled in the plane direction and in the downward direction. As a result, the variation in the areas and thickness of the formed silicide layers 80′ is suppressed. Therefore, the variation in the resistances of the whole resistor elements is suppressed, thus, the high-precision resist or elements are offered. In comparison with the first embodiment, an additional effect, in which the process for depositing the upper barrier layer 42, can be eliminated.

### 3. Third Embodiment

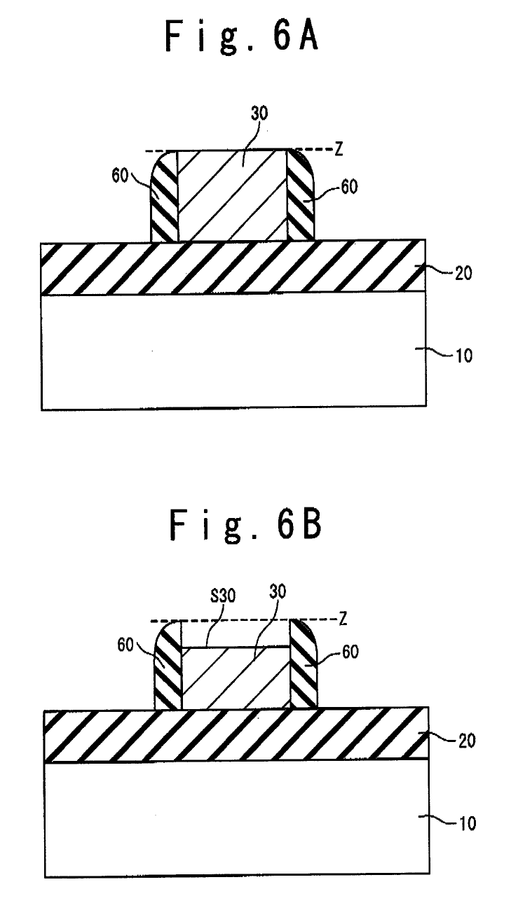

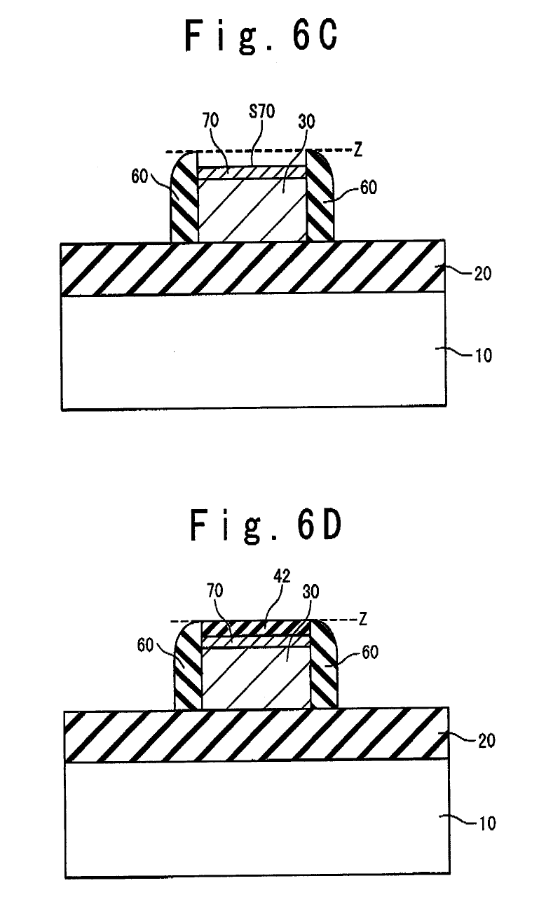

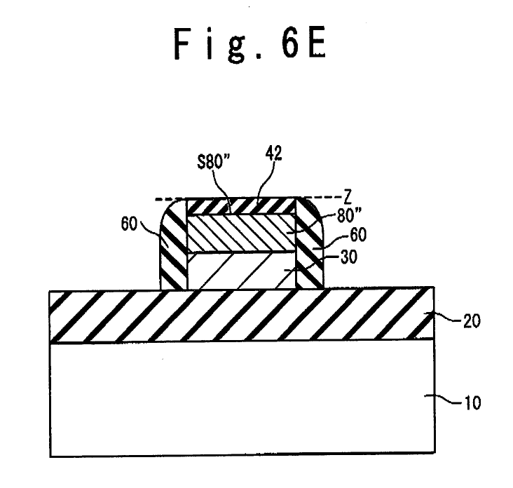

In a third embodiment of the present invention, the structure where the lower barrier layer 41 is eliminated from the resistance element according to the above-mentioned first embodiment is provided. Referring to FIGS. 6A-6E, the manufacturing process of the resistance element according to the present embodiment is explained. The explanations which already have described in the first embodiment are suitably omitted for avoiding redundant description.

First, as shown in FIG. 6A, the polysilicon structure including a polysilicon layer 30 with the thickness of about 1500 A is formed on the substrate 10 (element separation structure 20). The sidewall 60 is formed in on both sides of the polysilicon structure. The sidewall 60 is formed for surrounding all the sides of the polysilicon layer 30.

Subsequently, the polysilicon layer 30 is selectively etched about 500 A.

This is realizable by the selectivity etching or the etching employing the photoresist. As a result, as shown in FIG. 6B, the upper surface S30 of the polysilicon layer 30 will be located lower than the topmost part Z of the sidewall 60. Thus, the “space” surrounded by the upper surface S30 of the polysilicon layer 30 and the internal surface of the sidewall 60 are formed by selectively removing a part of the polysilicon layer 30.

Subsequently, as shown in FIG. 6C, the metal layer 70 for the silicidation is formed on the surface of the remaining polysilicon layer 30, i.e., the inside of the above “space.” This metal layer 70 is also formed so that the upper surface S70 will be lower than the topmost part Z of the sidewall 60.

Subsequently, as shown in FIG. 6D, the upper barrier layer 42 is formed on the metal layer 70. The upper barrier layer 42 is formed with the oxide film, the nitride film, or the oxynitride film, and plays a role to prevent the diffusion of the metal atoms. For example, the top barrier layer 42 is a thin oxide film with the thickness of about 10 A. Preferably, the upper barrier layer 42 is formed so that the upper surface thereof may be substantially aligned with the topmost part Z of the sidewall 60.

Subsequently, the heat treatment is performed and the silicidation occurs between a part of the polysilicon layer 30 and the metal layer 70. In this silicidation, the grain cannot grow over the sidewall 60. That is, the sidewall 60 defines the limit of the range for the grain growth and controls the grain growth in the plane direction. Similarly, the top barrier layer 42 controls the grain growth in the upward direction. As a result of such the silicidation, as shown in FIG. 6E, a silicide layer 80″ (for example, TiSi) surrounded by the top barrier layer 42 and the sidewall 60 as shown in FIG. 6E is formed. The upper surface S80″ of the silicide layer 80″ is located lower than the topmost part Z of the sidewall 60.

Then, the contact 100 and the wiring layer 110 are formed according to the process shown in FIGS. 4J and 4K which has already been described.

According to the present embodiment, the grain growth in the silicidation is controlled in the plane direction and in the upward direction. As a result, the variation of areas and thickness of the formed silicide layers 80″ is prevented. Therefore, the variation in the resistances of the whole resistor elements is prevented, thus, the high-precision resistor elements are offered. In comparison with the first embodiment, an additional effect, in which the process for forming a lamination structure including the lower polysilicon layer 31, the lower barrier layer 41, and the upper polysilicon layer 32, can be eliminated.

What is claimed is:

1. A method of manufacturing a resistor element, comprising:
(A) forming on a substrate, a polysilicon structure whose top layer is a polysilicon layer;
(B) forming a metal layer on said polysilicon layer:
(C) forming an upper barrier layer on said metal layer; and
(D) forming a silicide layer whose upper surface is covered with said upper barrier layer after said process (C) through a reaction between said polysilicon layer and said metal layer.

2. The method of manufacturing a resistor element according to claim 1, further comprising:
(E) forming a sidewall on a side of said polysilicon structure; and
(F) removing a portion of said polysilicon layer after said process (E) to form a space surrounded by an upper surface of said polysilicon structure and said sidewall,
wherein said processes (E) and (F) are carried out between said processes(A) and (B),
said metal layer is formed in said space during said step (B),
said silicide layer is formed so that a side thereof is surrounded by said sidewall during said process (D).

3. The method of manufacturing a resistor element according to claims 1, wherein said upper barrier layer is formed so that an upper surface thereof is aligned with a topmost part of said sidewall during said process (C).

4. The method of manufacturing a resistor element according to claim 1, wherein said process (A) comprising
(a1) forming a lower polysilicon layer on said substrate,
(a2) forming a lower barrier layer on said lower polysilicon layer, and
(a3) forming an upper polysilicon layer on said lower barrier layer as said polysilicon layer.

5. A resistor element comprising:
a polysilicon layer formed on a substrate;
a lower barrier layer formed on said polysilicon layer;
a silicide layer formed on said lower barrier layer; and
an upper barrier layer formed on said silicide layer.

6. The resistor element according to claim 5, further comprising:
a sidewall formed on a side of said polysilicon layer, said lower barrier layer, said silicide layer, and said upper barrier layer.

7. The resistor element according to claim 6, wherein an upper surface of said upper barrier layer is aligned with the topmost part of said sidewall.
